(19) United States
(12) Patent Application Publication
(10) Pub. No.: US 2026/0221704 A1
(43) Pub. Date: Jul. 30, 2026

(54) ELECTRICAL CONNECTION UNIT

(71) Applicant: Yazaki Corporation, Tokyo (JP)

(72) Inventors: Kazuhiko TSUCHIYA, Kakegawa-shi (JP); Hirotaka MUKASA, Kakegawa-shi (JP); Ryu SENOO, Kakegawa-shi (JP)

(73) Assignee: Yazaki Corporation, Tokyo (JP)

(21) Appl. No.: 19/574,813

(22) Filed: Mar. 23, 2026

Related U.S. Application Data
(63) Continuation of application No. PCT/JP2025/007992, filed on Mar. 5, 2025.

(30) Foreign Application Priority Data
Apr. 9, 2024 (JP) 2024-062569

(51) Int. Cl. H01R 25/16; H05K 7/20

(52) U.S. Cl. CPC H01R 25/161; H05K 7/20481

(57) ABSTRACT

An electrical connection unit includes: a first member; a second member; a first electronic component; a second electronic component; a first bus bar; a metal member; and a first heat conduction member. The first bus bar includes a first end, a second end, and an extending portion. The extending portion has a plate shape and extends along the first member. The metal member is disposed on a side opposite to the second member with respect to the first member. The first heat conduction member is disposed between the extending portion and the metal member. The first heat conduction member has a smaller outer shape than an outer shape of the extending portion. The first heat conduction member overlaps the extending portion at a position deviated to a side that is closer to a first end than a center of the extending portion.

### TECHNICAL FIELD

Embodiments of the present invention relate to an electrical connection unit.

This application is a Rule 53(b) Continuation of International Application No. PCT/JP2025/007992 filed on Mar. 5, 2025, claiming priority based on Japanese Patent Application No. 2024-062569 filed in Japan on Apr. 9, 2024, the content of which is incorporated herein by reference.

### BACKGROUND ART

Patent Document 1 discloses a junction box mounted on a vehicle. A plurality of electronic components are mounted in the junction box.

### CITATION LIST

### Patent Document

### Patent Document 1

Japanese Unexamined Patent Application, First Publication No. 2022-99475

### SUMMARY OF INVENTION

### Technical Problem

Incidentally, as an increase in energization time and/or energization current value in an electrified vehicle, it is predicted that the amount of heat generation will increase in the future. Therefore, an improvement in heat dissipation properties of an electrical connection unit is desired.

An embodiment provides an electrical connection unit capable of improving heat dissipation properties.

### Solution to Problem

An electrical connection unit according to an embodiment includes: a first member; a second member; a first electronic component; a second electronic component; a first bus bar; a metal member; and a first heat conduction member. The second member forms an accommodation space with the first member. The first electronic component is disposed in the accommodation space. The second electronic component is disposed in the accommodation space. The first bus bar includes a first end, a second end, and an extending portion. The first end is electrically connected to the first electronic component. The second end is electrically connected to the second electronic component. The extending portion has a plate shape and extends along the first member. The metal member is disposed on a side opposite to the second member with respect to the first member. The metal member includes a plate portion extending along the first member. In a case where a direction in which the first member and the second member face each other is a first direction, the first heat conduction member is disposed between the extending portion and the metal member in the first direction. In a case where an extending direction of the extending portion is a second direction, the first heat conduction member has an outer shape that is smaller than an outer shape of the extending portion in the second direction. The first heat conduction member overlaps the extending portion at a position deviated to a side closer to the first end than a center of the extending portion in the second direction when viewed from the first direction.

An electrical connection unit according to an embodiment includes: a first member; a second member; a first electronic component; a second electronic component; a first bus bar; a metal member; and a first heat conduction member. The second member forms an accommodation space with the first member. The first electronic component is disposed in the accommodation space. The second electronic component is disposed in the accommodation space. The first bus bar includes a first end, a second end, and an extending portion. The first end is electrically connected to the first electronic component. The second end is electrically connected to the second electronic component. The extending portion has a plate shape and extends along the first member. The metal member is disposed on a side opposite to the second member with respect to the first member. The metal member includes a plate portion extending along the first member. In a case where a direction in which the first member and the second member face each other is a first direction, the first heat conduction member is disposed between the extending portion and the metal member in the first direction. In a case where an extending direction of the extending portion is a second direction, the first heat conduction member has an outer shape that is smaller than a half of an outer shape of the extending portion in the second direction. The first heat conduction member overlaps the extending portion between a center of the extending portion in the second direction and the first end when viewed from the first direction.

An electrical connection unit according to an embodiment includes a first electrical connection module, a second electrical connection module, and a metal member. The second electrical connection module has an electrical function or an external connection destination that is different from that of the first electrical connection module. The first electrical connection module includes: a first member; a second member; a first electronic component; a second electronic component; a first bus bar; and a first heat conduction member. The second member forms a first accommodation space with the first member. The first electronic component is disposed in the first accommodation space. The second electronic component is disposed in the first accommodation space. The first heat conduction member includes a first end, a second end, and an extending portion. The first end is electrically connected to the first electronic component. The second end is electrically connected to the second electronic component. The extending portion has a plate shape and extends along the first member. In a case where a direction in which the first member and the second member face each other is a first direction, the first heat conduction member is disposed between the extending portion and the metal member in the first direction. The second electrical connection module includes the third member, a fourth member, a third electronic component, and a second bus bar. The fourth member forms a second accommodation space with the third member. The third electronic component is disposed in the second accommodation space. The second bus bar is electrically connected to the third electronic component. The metal member overlaps the first electrical connection module and the second electrical connection module when viewed from the first direction.

### Advantageous Effects of Invention

According to an embodiment, it is possible to improve heat dissipation properties of an electrical connection unit.

### BRIEF DESCRIPTION OF DRAWINGS

FIG. 1 is a perspective view illustrating an electrical connection unit according to a first embodiment.

FIG. 2 is a partial cross-sectional view of the electrical connection unit illustrated in FIG. 1 taken along the line II-II.

FIG. 3 is a partial cross-sectional view of the electrical connection unit illustrated in FIG. 1 taken along the line III-III.

FIG. 4 is a partial cross-sectional view illustrating an electrical connection unit according to a second embodiment.

### DESCRIPTION OF EMBODIMENTS

### FIRST EMBODIMENT

Hereinafter, a first embodiment will be described using the drawings. Note that “connection” is not limited to mechanical connection and may include electrical connection in the present disclosure. In other words, “connection” is not limited to a case where two elements that are connection targets are directly connected and may include a case where two elements that are connection targets are connected with another element interposed therebetween.

### Electrical Connection Unit

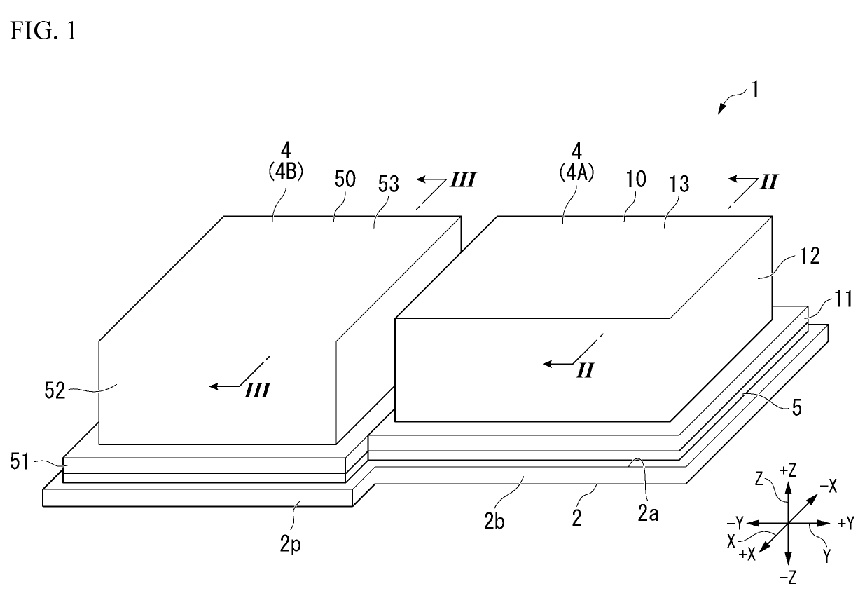

FIG. 1 is a perspective view illustrating an electrical connection unit 1 according to the first embodiment. The electrical connection unit 1 is, for example, a device mounted on an electrified vehicle such as an electric vehicle (EV), a hybrid electric vehicle (HEV), or a plug-in hybrid electric vehicle (PHEV). The electrical connection unit 1 is, for example, a connection device capable of electrically connecting a plurality of electric devices mounted on the electrified vehicle. Examples of the plurality of electric devices include, but are not limited to, a battery pack, an inverter, a power window (window opening and closing device), and a headlight. The electrical connection unit 1 may be referred to as an “electrical connection box” or a “junction box”. Note that the “electrical connection unit” referred to in the present disclosure is not limited to a configuration in which a plurality of junction boxes 4 are integrated as will be described later. The “electrical connection unit” may have, for example, only a configuration corresponding to one junction box 4.

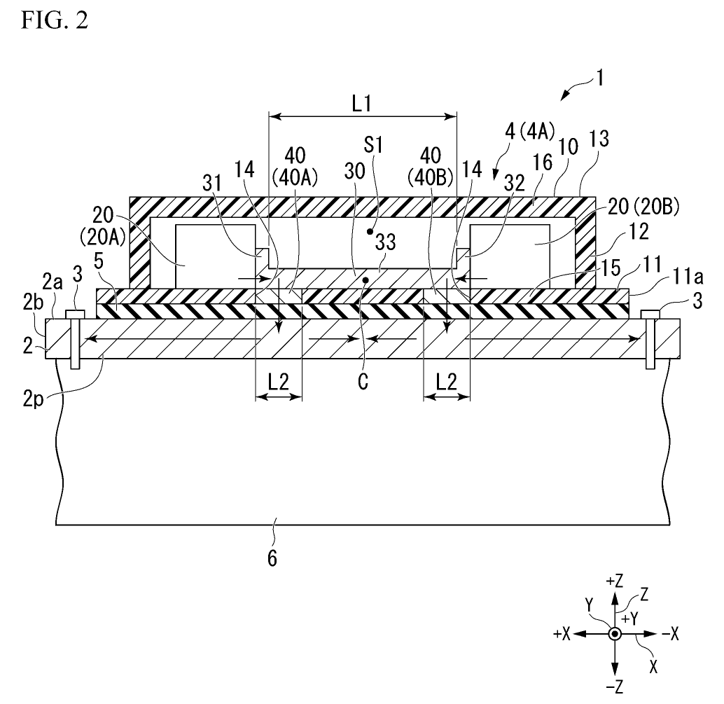

As illustrated in FIG. 1, the electrical connection unit 1 includes, for example, a metal member 2, a plurality of fixtures 3 (see FIG. 2), a plurality of junction boxes 4, and an insulating portion 5. In the present embodiment, the electrical connection unit 1 is mounted outside a battery pack of the electrified vehicle. Note that the installation location of the electrical connection unit 1 is not limited to the above example. The electrical connection unit 1 may be mounted inside the battery pack, near another electric device, or near a cooling device.

### Metal Member

The metal member 2 is a member that is formed of a metal material and has higher heat conductivity than housings 10 of the junction boxes 4, which will be described later. The metal member 2 is formed of a metal material such as aluminum or an aluminum alloy, for example. In the present embodiment, the metal member 2 includes a plate portion 2p extending along bottom walls 11 of the housings 10 of the junction boxes 4. Note that the metal member 2 may be formed only of the plate portion 2p or may have an edge portion or the like rising from the outer peripheral edge of the plate portion 2p.

Hereinafter, a direction in which the metal member 2 and the junction boxes 4 face each other will be referred to as a Z direction (first direction). A direction from the metal member 2 toward the junction boxes 4 is defined as a +Z direction. A direction from the junction boxes 4 toward the metal member 2 is defined as a -Z direction. Furthermore, directions intersecting each other inside a plane facing the Z direction are defined as an X direction and a Y direction. In the example of the present embodiment, the X direction, the Y direction, and the Z direction are directions orthogonal to each other. In this example, the Z direction is the “up-down direction”. In this example, the +Z direction is the upward direction, and the -Z direction is the downward direction. However, the posture in which the electrical connection unit 1 is mounted is not limited to the above-described example.

In the present embodiment, the plate portion 2p of the metal member 2 has a plate shape extending in the X direction and the Y direction. The plate portion 2p of the metal member 2 has a mounting surface (supporting surface) 2a as one surface facing the +Z direction. The mounting surface 2a is a plane along the X direction and the Y direction, for example. The plurality of junction boxes 4 are mounted on the mounting surface 2a via an insulating portion 5, which will be described later.

The metal member 2 is formed to be slightly larger than the plurality of junction boxes 4, which will be described later, when viewed from the Z direction. For example, an outer peripheral edge 2b of the metal member 2 is formed along a side further outward than the plurality of junction boxes 4 when viewed from the Z direction. For example, the outer peripheral edge 2b of the metal member 2 is formed along the outer shapes of the plurality of junction boxes 4. Note that the metal member 2 may be provided with an additional heat dissipation structure such as a heat dissipation fin.

### Fixtures

FIG. 2 is a partial cross-sectional view of the electrical connection unit 1 illustrated in FIG. 1 taken along the line II-II. As illustrated in FIG. 2, the fixtures 3 fix the metal member 2 to an external attachment body 6. The attachment body 6 is, for example, the battery pack on which the electrical connection unit 1 is mounted. Note that the attachment body 6 may not be the battery pack and may be a vehicle body, for example. The fixtures 3 are, for example, bolts. The fixtures 3 penetrate the metal member 2 from the mounting surface 2a in the -Z direction. The fixtures 3 are provided to be close to the outer peripheral edge 2b of the metal member 2. The fixtures 3 are provided on the side further inward than the outer peripheral edge 2b of the metal member 2 and on the side further outward than the junction boxes 4, which will be described later, when viewed from the Z direction. The fixtures 3 are made of, for example, metal. The fixtures 3 transmit heat from the metal member 2 to the attachment body 6.

### Junction Boxes

Each of the plurality of junction boxes 4 is a connection device that can electrically connect a plurality of electric devices. The junction boxes 4 may be referred to as “electrical connection boxes”. The plurality of junction boxes 4 include, for example, a first junction box 4A and a second junction box 4B (see FIG. 1). The first junction box 4A and the second junction box 4B have different electrical functions, for example. Alternatively/additionally, the first junction box 4A and the second junction box 4B may have different external connection destinations (connected electric devices). For example, the first junction box 4A is electrically connected to a first electric device disposed outside the electrical connection unit 1. The second junction box 4B is electrically connected to a second electric device disposed outside the electrical connection unit 1. The second electric device is an electric device for a different application than that of the first electric device. The first junction box 4A is an example of the “first electrical connection module”. The second junction box 4B is an example of the “second electrical connection module”. Hereinafter, the first junction box 4A and the second junction box 4B will be simply referred to as “junction boxes 4” when these are not distinguished from each other.

The plurality of junction boxes 4 are disposed to face the metal member 2 in the Z direction. The plurality of junction boxes 4 are mounted on the mounting surface 2a of the metal member 2 such that they are located to be close to each other. The plurality of junction boxes 4 may be in contact with each other. The plurality of junction boxes 4 are disposed inside the outer peripheral edge 2b of the metal member 2 when viewed from the Z direction.

### First Junction Box

First, the first junction box 4A will be described.

As illustrated in FIG. 2, the first junction box 4A includes, for example, a housing 10, a plurality of electronic components 20, a bus bar 30, and a plurality of heat conduction members 40.

### Housing

The housing 10 is a member that forms an outline of the first junction box 4A. The housing 10 is attached to the mounting surface 2a of the metal member 2 with the insulating portion 5 interposed therebetween, for example. Alternatively, the housing 10 may be attached to the mounting surface 2a of the metal member 2. The housing 10 accommodates the plurality of electronic components 20 that generate heat when energized. The housing 10 is non-metallic. The housing 10 is made of an insulating material such as a synthetic resin and has insulating properties. The housing 10 of the present embodiment is formed of, for example, a resin material such as a polypropylene.

The housing 10 is formed into a rectangular parallelepiped shape, for example. The housing 10 includes, for example, a bottom wall 11, a peripheral wall 12, and an upper wall 13. The bottom wall 11 is a wall facing the mounting surface 2a of the metal member 2 in the Z direction. The bottom wall 11 extends in the X direction and the Y direction. The bottom wall 11 extends along the mounting surface 2a of the metal member 2. The bottom wall 11 projects outward from the peripheral wall 12, for example, when viewed from the Z direction. The bottom wall 11 has through-holes 14 penetrating the bottom wall 11 in the Z direction. In the through-holes 14, heat conduction members 40, which will be described later, are disposed. One through-hole 14 is formed for each of the electronic components 20.

The peripheral wall 12 extends in the +Z direction from the bottom wall 11. The peripheral wall 12 is located on the side further inward than the outer peripheral edge 11a of the bottom wall 11 when viewed from the Z direction. The peripheral wall 12 is formed along an outer peripheral edge 11a of the bottom wall 11. The upper wall 13 is disposed to face the bottom wall 11 in the Z direction. The upper wall 13 closes an opening of the peripheral wall 12 on the +Z direction side.

In the present embodiment, the housing 10 includes a first member 15 and a second member 16. The first member 15 includes, for example, the above-described bottom wall 11. The second member 16 includes, for example, the above-described peripheral wall 12 and upper wall 13. The housing 10 is formed by the first member 15 and the second member 16 being combined. An accommodation space S1 in which the plurality of electronic components 20 are accommodated is formed between the first member 15 and the second member 16. The accommodation space S1 is an example of the “first accommodation space”. Instead of the above example, the first member 15 may have the above-described bottom wall 11 and peripheral wall 12. The second member 16 may be formed only of the upper wall 13. Also, the second member 16 may be formed of an insulating film or the like instead of the wall made of the synthetic resin.

### Electronic Components

The plurality of electronic components 20 are accommodated in the accommodation space S1 of the housing 10. In the present embodiment, the plurality of electronic components 20 include a first electronic component 20A and a second electronic component 20B. The electronic components 20A and 20B are, for example, connectors, fuses, relays (for example, mechanical relays or semiconductor relays), capacitors, branch components, electronic control units, or an electronic component unit in which two or more of these are unitized. Note that the types of the electronic components 20A and 20B are not limited to the above examples. The electronic components 20A and 20B may be components of the same type or may be components of different types. The electronic components 20A and 20B are, for example, heat generating components that generate heat when energized. Hereinafter, the electronic components 20A and 20B will be referred to as “electronic components 20” in a case where these are not distinguished.

In the illustrated example, the first electronic component 20A and the second electronic component 20B are arranged in the X direction. The first electronic component 20A and the second electronic component 20B are disposed, for example, on the surface of the bottom wall 11 exposed to the accommodation space S1. The first electronic component 20A and the second electronic component 20B are disposed along the bottom wall 11. The first electronic component 20A and the second electronic component 20B are fixed to the bottom wall 11, for example. Alternatively, the first electronic component 20A and the second electronic component 20B may be disposed along the peripheral wall 12 or the upper wall 13. The first electronic component 20A and the second electronic component 20B may be fixed to the peripheral wall 12 or the upper wall 13.

### Bus Bar

The bus bar 30 is a connection member that electrically connects the first electronic component 20A and the second electronic component 20B. For example, the entire bus bar 30 is accommodated in the housing 10. The bus bar 30 is an example of the “first bus bar”. For example, the entire bus bar is formed in a plate shape. The bus bar 30 includes, for example, a first end 31, a second end 32, and an extending portion 33.

The first end 31 is located at one end of the bus bar 30. The first end 31 projects in the +Z direction from the extending portion 33, for example. The first end 31 is formed, for example, by being bent in the +Z direction from one end of the extending portion 33. The first end 31 is adjacent to a terminal of the first electronic component 20A in the X direction (or the Y direction). The first end 31 is connected to the terminal of the first electronic component 20A. The first end 31 is electrically and thermally connected to the first electronic component 20A.

The second end 32 is located at the other end of the bus bar 30. The second end 32 projects in the +Z direction from the extending portion 33, for example. The second end 32 is formed, for example, by being bent in the +Z direction from the other end of the extending portion 33. The second end 32 is adjacent to a terminal of the second electronic component 20B in the X direction (or the Y direction). The second end 32 is connected to the terminal of the second electronic component 20B. The second end 32 is electrically and thermally connected to the second electronic component 20B.

The extending portion 33 is a plate-shaped portion extending along the bottom wall 11 (first member 15). For example, the extending portion 33 extends between the first end 31 and the second end 32 so as to connect the first end 31 and the second end 32. Note that the extending portion 33 is not limited to a portion extending between the first end 31 and the second end 32. The extending portion 33 may be, for example, a branch portion extending from the first end 31 in a direction different from the second end 32. In the present embodiment, the extending portion 33 overlaps the plurality of through-holes 14 of the bottom wall 11 when viewed from the Z direction.

In the present embodiment, the extending portion 33 extends in the X direction. The X direction is an extending direction of the extending portion 33 and is an example of the “second direction”. Note that the extending portion 33 may be bent from the X direction to the Y direction and/or may be bent and extended from the Y direction to the X direction. In this case, the second direction is a direction that follows the extending portion 33 while bent.

### Heat Conduction Member

Heat conduction members 40 are members that conduct heat from the bus bar 30 to the metal member 2. The heat conduction members 40 are, for example, members having higher heat conductivity than the bottom wall 11. Although the heat conduction members 40 are, for example, metal members, heat conductive sheets, heat conductive fillers, heat conductive pastes, heat conductive rubber, or a combination thereof, the heat conduction members 40 are not limited to the examples listed above. In the present embodiment, the plurality of heat conduction members 40 include a first heat conduction member 40A and a second heat conduction member 40B. Hereinafter, the first heat conduction member 40A and the second heat conduction member 40B will be simply referred to as “heat conduction members 40” in a case where these are not distinguished from each other.

The heat conduction members 40 are disposed between the extending portion 33 of the bus bar 30 and the metal member 2 in the Z direction. In the present embodiment, the heat conduction members 40 are disposed in the through-holes 14 of the bottom wall 11 and are in contact with the extending portion 33 of the bus bar 30. For example, the heat conduction members 40 are embedded in the through-holes 14 of the bottom wall 11 without any gaps and are integrated with the housing 10. Alternatively, gaps may be present between the heat conduction members 40 and inner circumferential surfaces of the through-holes 14. One heat conduction member 40 is provided in each through-hole 14. In other words, one heat conduction member 40 is provided to correspond to each electronic component 20.

A length L2 of the heat conduction members 40 (the outer shape of the heat conduction members 40) in the extending direction of the extending portion 33 of the bus bar 30 is shorter than a length L1 of the extending portion 33 of the bus bar 30 in the extending direction (the outer shape of the extending portion 33). For example, the length L2 of the heat conduction members 40 (the outer shape of the heat conduction members 40) in the extending direction of the extending portion 33 of the bus bar 30 is shorter than a half of the length L1 of the extending portion 33 of the bus bar 30 in the extending direction (the outer shape of the extending portion 33).

In the present embodiment, the first heat conduction member 40A overlaps the extending portion 33 between a center C of the extending portion 33 in the extending direction and the first end 31 when viewed from the Z direction. The first heat conduction member 40A is disposed to be deviated closer to the first end 31 than to the center C of the extending portion 33 in the extending direction. For example, the distance between the first end 31 (or the first electronic component 20A) and the first heat conduction member 40A is shorter than the distance between the center C of the extending portion 33 in the extending direction and the first heat conduction member 40A. For example, the first heat conduction member 40A may overlap the first end 31 or the first electronic component 20A when viewed from the Z direction.

Similarly, the second heat conduction member 40B overlaps the extending portion 33 between the center C of the extending portion 33 in the extending direction and the second end 32 when viewed from the Z direction. The second heat conduction member 40B is disposed to be deviated closer to the second end 32 than to the center C of the extending portion 33 in the extending direction. For example, the distance between the second end 32 (or the second electronic component 20B) and the second heat conduction member 40B is shorter than the distance between the center C of the extending portion 33 in the extending direction and the second heat conduction member 40B. For example, the second heat conduction member 40B may overlap the second end 32 or the second electronic component 20B when viewed from the Z direction.

### Second Junction Box

Next, the second junction box 4B will be described.

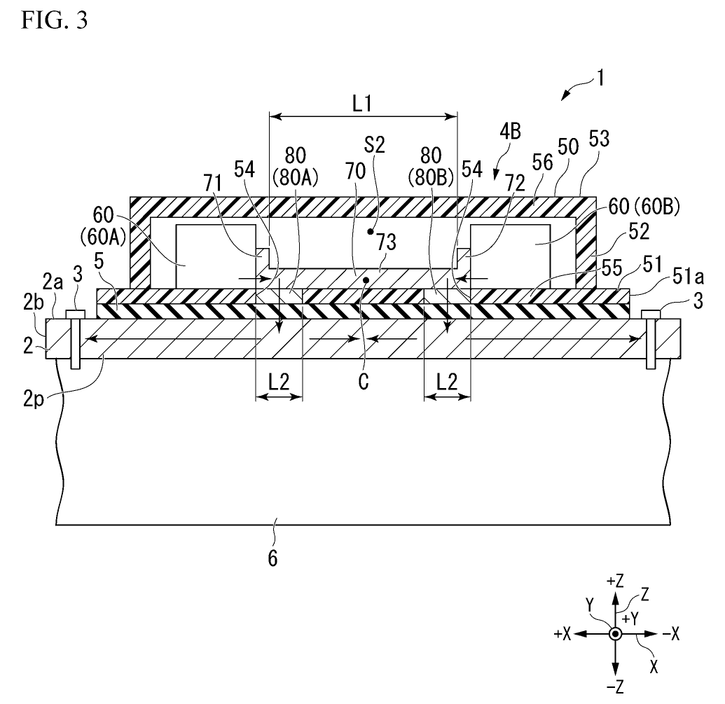

FIG. 3 is a partial cross-sectional view of the electrical connection unit illustrated in FIG. 1 taken along the line III-III. The second junction box 4B includes, for example, a housing 50, a plurality of electronic components 60, a bus bar 70, and a plurality of heat conduction members 80.

Note that details of the second junction box 4B are similar to those of the first junction box 4A. For the details of the second junction box 4B, for example, in the description of the first junction box 4A, the “housing 10” may be read as a “housing 50” instead, the “electronic component 20” may be read as an “electronic component 60” instead, the “first electronic component 20A” may be read as a “third electronic component 60A” instead, the “second electronic component 20B” may be read as a “fourth electronic component 60B” instead, the “bus bar 30” may be read as a “bus bar 70” instead, the “heat conduction member 40” may be read as a “heat conduction member 80” instead, the “first heat conduction member 40A” may be read as a “third heat conduction member 80A” instead, and the “second heat conduction member 40B” may be read as a “fourth heat conduction member 80B” instead. Furthermore, the “bottom wall 11”, the “peripheral wall 12”, the “upper wall 13”, the “first member 15”, the “second member 16”, and the “accommodation space S1” of the housing 10 may be read as a “bottom wall 51”, a “peripheral wall 52”, an “upper wall 53”, a “third member 55”, a “fourth member 56”, and an “accommodation space S2” of the housing 50 instead, respectively. The accommodation space S2 is an example of the "second accommodation space”. Also, the “first end 31”, the “second end 32”, and the “extending portion 33” of the bus bar 30 may be read as a “first end 71”, a “second end 72”, and an “extending portion 73” of the bus bar 70 instead, respectively. The bus bar 70 is an example of the “second bus bar”.

The first junction box 4A and the second junction box 4B may be electrically connected or may not be electrically connected. The accommodation space S1 and the accommodation space S2 are separated, for example.

In the present embodiment, the metal member 2 is located on the side opposite to the second member 16 (the -Z direction side) with respect to the first member 15 of the housing 10. Similarly, the metal member 2 is located on the side opposite to the fourth member 56 (the -Z direction side) with respect to the third member 55 of the housing 50. The metal member 2 overlaps the first junction box 4A and the second junction box 4B when viewed from the Z direction.

### Insulating Portion

The insulating portion 5 is disposed between the electronic components 20 and 60 and the metal member 2 and insulates the electronic components 20 and 60 from the metal member 2. Also, the insulating portion 5 is disposed between the bus bars 30 and 70 and the metal member 2 and insulates the bus bars 30 and 70 from the metal member 2. Moreover, the insulating portion 5 is disposed between the heat conduction members 40 and 80 and the metal member 2 and insulates the heat conduction members 40 and 80 from the metal member 2.

The insulating portion 5 is disposed, for example, between the bottom walls 11 and 51 of the housings 10 and 50 and the metal member 2. The insulating portion 5 is in close contact with the metal member 2, the bottom walls 11 and 51, and the heat conduction members 40 and 80 without any gaps. The insulating portion 5 is an insulating sheet along the X direction and the Y direction. The insulating portion 5 is formed to have the same shape as those of the bottom walls 11 and 51 of the housings 10 and 50 and have a size similar to those of the bottom walls 11 and 51 of the housings 10 and 50 when viewed from the Z direction. The insulating portion 5 covers the entire bottom walls 11 and 51 of the housings 10 and 50 from the -Z direction. The insulating portion 5 is interposed between the heat conduction members 40 and 80 and the metal member 2 and is in close contact with each of the heat conduction members 40 and 80 and the metal member 2, for example.

Note that the insulating portion 5 may be provided inside the housings 10 and 50 instead of being disposed between the bottom walls 11 and 51 of the housings 10 and 50 and the metal member 2. For example, the insulating portion 5 may be provided between the bottom walls 11 and 51 of the housings 10 and 50 and the bus bars 30 and 70.

### Effects

The first junction box 4A includes the heat conduction members 40 disposed between the extending portion 33 of the bus bar 30 and the metal member 2 in the Z direction. Therefore, a part of heat generated by the first electronic component 20A of the first junction box 4A is transmitted to the extending portion 33 of the bus bar 30. A part of the heat transmitted from the first electronic component 20A to the extending portion 33 of the bus bar 30 is transmitted to the metal member 2 outside the housing 10 through the first heat conduction member 40A. The heat transmitted to the metal member 2 is released to the outside of the housing 10. Similarly, a part of heat generated by the second electronic component 20B of the first junction box 4A is transmitted to the extending portion 33 of the bus bar 30. A part of the heat transmitted from the second electronic component 20B to the extending portion 33 of the bus bar 30 is transmitted to the metal member 2 outside the housing 10 through the second heat conduction member 40B. The heat transmitted to the metal member 2 is released to the outside of the housing 10. Such a flow of heat similarly occurs in the second junction box 4B as well.

### Advantages

Here, a junction box 4 without the heat conduction members 40 will be considered as a comparative example. In such a configuration of the comparative example, heat generated by the electronic component 20 at the time of energization moves from the electronic component 20 to the bus bar 30 and is released to the air in the housing 10 from the bus bar 30.

By the way, it is predicted that energization time and/or an energization current value increases in an electrified vehicle due to extension of a drivable distance of the electric vehicle, reduction of a charging time, and the like in the future. If the energization time and/or the energization current value increases, the amount of heat generation in the junction box 4 increases. In this case, there is a possibility that a temperature rise of the electronic component 20 will increase if the heat is only released from the bus bar 30 to the air inside the housing 10.

Thus, the electrical connection unit 1 includes the first member 15, the second member 16, the first electronic component 20A, the second electronic component 20B, the bus bar 30, the metal member 2, and the first heat conduction member 40A in the present embodiment. The second member 16 forms the accommodation space S1 with the first member 15. The first electronic component 20A is disposed in the accommodation space S1. The second electronic component 20B is disposed in the accommodation space S1. The bus bar 30 includes the first end 31, the second end 32, and the extending portion 33. The first end 31 is electrically connected to the first electronic component 20A. The second end 32 is electrically connected to the second electronic component 20B. The extending portion 33 has a plate shape and extends along the first member 15. The metal member 2 is disposed on the side opposite to the second member 16 with respect to the first member 15. The metal member 2 includes the plate portion 2p extending along the first member 15. In the case where the direction in which the first member 15 and the second member 16 face each other is the first direction, the first heat conduction member 40A is disposed between the extending portion 33 and the metal member 2 in the first direction. In the case where the extending direction of the extending portion 33 is the second direction, the first heat conduction member 40A has a smaller outer shape than the extending portion 33 in the second direction. The first heat conduction member 40A overlaps the extending portion 33 at a position deviated to the side closer to the first end 31 than to the center C of the extending portion 33 in the second direction when viewed from the first direction.

According to such a configuration, it is possible to transmit a part of the heat generated by the first electronic component 20A to the metal member 2 by the first heat conduction member 40A and to release the part of the heat through the metal member 2. It is thus possible to improve heat dissipation properties of the electrical connection unit 1.

Here, if the temperature of the electrical connection unit 1 rises, for example, then a difference may occur in the amounts of thermal expansion of the first member 15 and the metal member 2 due to a difference in linear expansion coefficients of the first member 15 and the metal member 2. If a difference occurs in the amounts of expansion of the first member 15 and the metal member 2, then a shear force in the X direction or the Y direction may act between the first member 15 and the metal member 2.

However, the first heat conduction member 40A has a smaller outer shape than the extending portion 33 of the bus bar 30 in the second direction according to the above configuration of the present embodiment. Therefore, even in a case where a shear force acts between the first member 15 and the metal member 2, a load acting on the first heat conduction member 40A is smaller than that in a case where a heat conduction member that is larger than the entire length of the bus bar 30 is disposed, and it is thus possible to extend the product life of the electrical connection unit 1. On the other hand, the first heat conduction member 40A overlaps the extending portion 33 at a position that is closer to the first end 31 than to the center C of the extending portion 33 of the bus bar 30 in the second direction when viewed from the first direction in the present embodiment. In other words, the first heat conduction member 40A overlaps the extending portion 33 of the bus bar 30 at a position that is relatively close to the first electronic component 20A. Therefore, even in a case where the small first heat conduction member 40A as described above is provided, it is possible to efficiently release the heat generated in the first electronic component 20A to the metal member 2. It is thus possible to improve heat dissipation properties of the electrical connection unit 1.

From another viewpoint, the first heat conduction member 40A has an outer shape that is smaller than a half of the extending portion 33 of the bus bar 30 in the second direction. Therefore, even in a case where a shear force acts between the first member 15 and the metal member 2, a load acting on the first heat conduction member 40A is smaller than that in a case where a heat conduction member that is larger than the entire length of the bus bar 30 is disposed, and it is thus possible to extend the product life of the electrical connection unit 1. On the other hand, the first heat conduction member 40A overlaps the extending portion 33 between the center C of the extending portion 33 of the bus bar 30 in the second direction and the first end 31 when viewed from the first direction. In other words, the first heat conduction member 40A overlaps the extending portion 33 of the bus bar 30 at a position that is relatively close to the first electronic component 20A. Therefore, even in a case where the small first heat conduction member 40A as described above is provided, it is possible to efficiently release the heat generated in the first electronic component 20A to the metal member 2. It is thus possible to improve heat dissipation properties of the electrical connection unit 1.

In the present embodiment, the first electronic component 20A and the second electronic component 20B are disposed along the first member 15. According to such a configuration, the extending portion 33 of the bus bar 30 can be easily disposed along the first member 15. It is thus possible to further improve heat dissipation properties of the electrical connection unit 1.

In the present embodiment, the second heat conduction member 40B is disposed between the extending portion 33 of the bus bar 30 and the metal member 2 in the first direction. The second heat conduction member 40B has a smaller outer shape than the extending portion 33 of the bus bar 30 in the second direction. The second heat conduction member 40B is disposed so as to separate away from the first heat conduction member 40A. The second heat conduction member 40B overlaps the extending portion 33 between the center C of the extending portion 33 of the bus bar 30 in the second direction and the second end 32. According to such a configuration, even in a case where a shear force acts between the first member 15 and the metal member 2, a load acting on the second heat conduction member 40B is smaller than that in a case where the heat conduction member that is larger than the entire length of the bus bar 30 is disposed, and it is thus possible to extend the product life of the electrical connection unit 1. On the other hand, the second heat conduction member 40B overlaps the extending portion 33 between the center C of the extending portion 33 of the bus bar 30 in the second direction and the second end 32 in the present embodiment. In other words, the second heat conduction member 40B overlaps the extending portion 33 of the bus bar 30 at a position that is relatively close to the second electronic component 20B. Therefore, even in a case where the small second heat conduction member 40B as described above is provided, it is possible to efficiently release the heat generated in the second electronic component 20B to the metal member 2. It is thus possible to further improve heat dissipation properties of the electrical connection unit 1.

In the present embodiment, the first member 15 has the through-holes 14 penetrating the first member 15 in the first direction. The first heat conduction member 40A is disposed in the through-holes 14. According to such a configuration, heat of the bus bar 30 is easily transmitted to the metal member 2 by the first heat conduction member 40A. It is thus possible to further improve heat dissipation properties of the electrical connection unit 1.

If a gap is present between the first heat conduction member 40A and the inner circumferential surface of the through-hole 14, for example, the shear force becomes more unlikely to act on the first heat conduction member 40A. For example, in a case where the first heat conduction member 40A is formed of a material with a higher elastic modulus (a material that is easily elastically deformed) as compared with the first member 15, the shear force becomes more unlikely to act on the first heat conduction member 40A.

In the present embodiment, the electrical connection unit 1 includes the first junction box 4A and the second junction box 4B. At least either the electrical function or the external connection destination of the second junction box 4B is different from that of the first junction box 4A. The first junction box 4A includes the first member 15, the second member 16, the first electronic component 20A, the second electronic component 20B, the bus bar 30, and the first heat conduction member 40A. The second junction box 4B includes the third member 55, the fourth member 56, the third electronic component 60A, and the bus bar 70. The fourth member 56 forms the accommodation space S2 with the third member 55. The third electronic component 60A is disposed between the third member 55 and the fourth member 56. The bus bar 70 is electrically connected to the third electronic component 60A. The metal member 2 overlaps the first junction box 4A and the second junction box 4B when viewed from the first direction. According to such a configuration, it is possible to release the heat transmitted from the first electronic component 20A of the first junction box 4A to the metal member 2 via the first heat conduction member 40A using the metal member 2 having a wide heat dissipation area overlapping the plurality of junction boxes 4. It is thus possible to further improve heat dissipation properties of the electrical connection unit 1.

According to the above configuration, the first junction box 4A and the second junction box 4B can be easily supported by one metal member 2. As a result, the first junction box 4A and the second junction box 4B can be easily handled integrally.

In the present embodiment, the bus bar 70 of the second junction box 4B includes the plate-shaped extending portion 73 extending along the third member 55. The second junction box 4B further includes the third heat conduction member 80A disposed between the extending portion 73 of the bus bar 70 and the metal member 2 in the first direction. According to such a configuration, it is possible to transmit a part of heat generated by the third electronic component 60A from the extending portion 73 of the bus bar 70 to the metal member 2 by the third heat conduction member 80A. It is thus possible to further improve heat dissipation properties of the electrical connection unit 1.

In the present embodiment, the metal member 2 is formed in a plate shape extending in a direction intersecting the Z direction. With such a plate shape of the metal member 2, the electrical connection unit 1 can exert the effect of dissipating the heat to the outside of the housing 10 by the metal member 2 while curbing an increase in size in the Z direction. Also, the attachability of the electrical connection unit 1 is improved.

In the present embodiment, the first heat conduction member 40A is in contact with the extending portion 33 of the bus bar 30. It becomes easier to transmit the heat from the first heat conduction member 40A to the metal member 2 by the first heat conduction member 40A being in contact with the extending portion 33 of the bus bar 30.

In the present embodiment, the electrical connection unit 1 includes the insulating portion 5 disposed between the metal member 2 and the electronic component 20. The insulating portion 5 insulates the metal member 2 from the electronic component 20. In the electrical connection unit 1, leakage of a current from the electronic component 20 to the metal member 2 can be curbed by the insulating portion 5.

### SECOND EMBODIMENT

Hereinafter, a second embodiment will be described using the drawings. Among the configurations in the second embodiment, configurations that are common to those in the first embodiment will be denoted by the same names and reference signs, and description thereof will be appropriately omitted. Note that configurations other than those described below are the same as the configurations in the first embodiment.

### Electrical Connection Unit

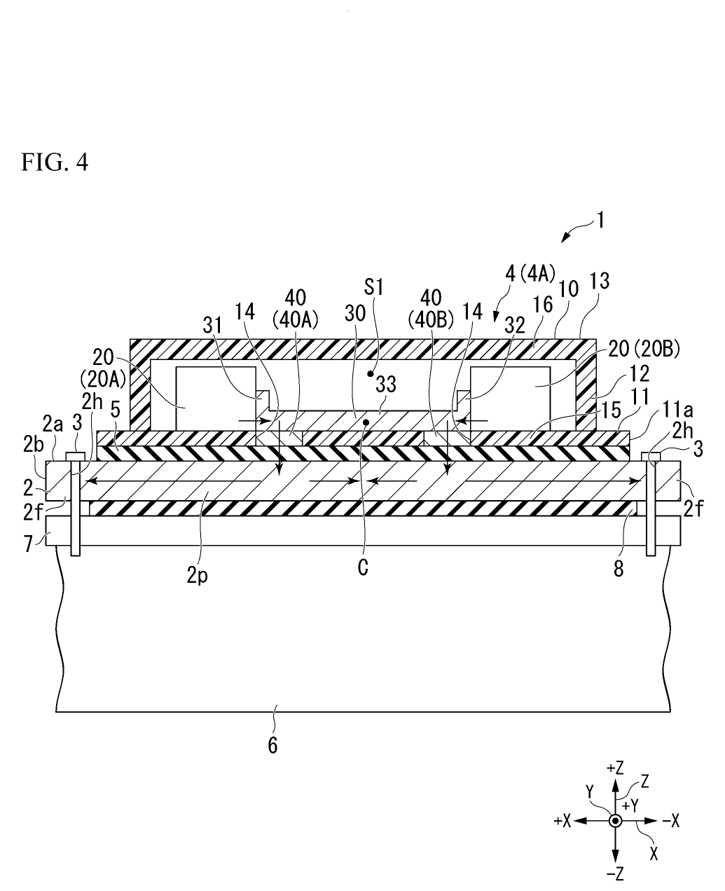

FIG. 4 is a partial cross-sectional view illustrating an electrical connection unit 1 according to the second embodiment. The electrical connection unit 1 according to the second embodiment further includes a cooling mechanism 7 and a heat conduction member 8 in addition to the configurations described above in the first embodiment.

### Cooling Mechanism

The cooling mechanism 7 is a mechanism that promotes heat dissipation of a metal member 2. The cooling mechanism 7 is stacked on the metal member 2 in the Z direction. The cooling mechanism 7 is attached to a surface of the metal member 2 on the side opposite to a mounting surface 2a. The cooling mechanism 7 cools the metal member 2. Examples of the cooling mechanism 7 include a water-cooling plate attached to a vehicle body side. The cooling mechanism 7 is attached to an attachment body 6 such as a battery pack.

In the present embodiment, a plate portion 2p of the metal member 2 includes fixing portions 2f attached to the cooling mechanism 7. Fixing portions 2f of the metal member 2 have attachment holes 2h to which fixtures 3 are attached. For example, the fixtures 3 pass through the attachment holes 2h of the metal member 2 and are engaged with the cooling mechanism 7. The fixtures 3 are, for example, bolts.

### Heat Conduction Member

The heat conduction member 8 is disposed between the metal member 2 and the cooling mechanism 7. The heat conduction member 8 is thermally connected to the metal member 2 and the cooling mechanism 7. The heat conduction member 8 transmits heat of the metal member 2 to the cooling mechanism 7. The heat conduction member 8 is an insulating material with heat conductivity, such as a heat conductive sheet, a heat conductive paste (grease), or heat conductive rubber, for example. The heat conduction member 8 is disposed on a surface of the metal member on the side opposite to the mounting surface 2a of the metal member 2 in the Z direction. The heat conduction member 8 is compressed in the Z direction by the metal member 2 and the cooling mechanism 7, for example, and brings the metal member 2 and the cooling mechanism 7 into close contact without any gap. The heat conduction member 8 is formed to have the same shape as that of a bottom wall 11 of a housing 10 and a size similar to that of the bottom wall 11 of the housing 10 when viewed from the Z direction. The heat conduction member 8 overlaps an entire heat conduction member 40 and an entire insulating portion 5 in the Z direction.

### Advantages

In the present embodiment, the electrical connection unit 1 further includes the cooling mechanism 7 that cools the metal member 2 and the heat conduction member 8 that is disposed between the metal member 2 and the cooling mechanism 7 and is thermally connected to the metal member 2 and the cooling mechanism 7. The electrical connection unit 1 can transmit heat transmitted to the metal member 2 to the cooling mechanism 7 via the heat conduction member 8. It is thus possible to further improve heat dissipation properties of the electrical connection unit 1.

### OTHER MODIFICATION EXAMPLES

In the example of each of the above-described embodiments, the X direction, the Y direction, and the Z direction are directions orthogonally intersecting each other. Note that it is only necessary for the X direction, the Y direction, and the Z direction to intersect each other and the X direction, the Y direction, and the Z direction may not orthogonally intersect each other. Although the Z direction is defined as the “up-down direction”, the Z direction may not be the “up-down direction”. For example, the Z direction may be a direction inclined with respect to the “up-down direction” or may be a “horizontal direction”. Although the +Z direction has been defined as the upward direction and the -Z direction has been defined as the downward direction, the +Z direction may be the downward direction and the -Z direction may be the upward direction.

The heat conduction member 40 may be an insulating material with heat conductivity, such as a heat conductive sheet, a heat conductive paste (grease), or heat conductive rubber. In this case, since current leakage from the electronic component 20 to the metal member 2 is curbed by the heat conduction member 40, the insulating portion 5 becomes unnecessary. In this case, the heat conduction member 40 is in direct contact with both the metal member 2 and the bus bar 30.

Furthermore, the bus bar 30 may be drawn out to the outside of the housing 10 and may be thermally connected to the heat conduction member 40 outside the housing 10. The bus bar 30 drawn out to the outside of the housing 10 may not be connected directly to the electronic component 20 and may be connected to an input/output portion of the junction box 4, for example.

In the example of each of the above-described-embodiments, the cooling mechanism 7 is a water-cooling plate attached to a vehicle body side, for example. Note that the cooling mechanism 7 may be another member having a heat dissipation structure, such as a heat dissipation fin, or a cooling mechanism 7 based on a cooling method using a liquid other than water.

In each of the above-described embodiments, in the metal member 2, it is possible to improve heat dissipation properties of the electrical connection unit 1 by the metal member having a wide heat dissipation area overlapping the first junction box 4A and the second junction box 4B when viewed from the first direction. From this viewpoint, it is not essential that the outer shape of the heat conduction member 40 in the second direction be smaller than that of the extending portion 33. It is also not essential that the heat conduction member 40 overlaps the extending portion 33 at the position deviated to a position closer to the first end 31 than to the center of the extending portion 33 in the second direction.

### INDUSTRIAL APPLICABILITY

According to the present disclosure, it is possible to improve heat dissipation properties of the electrical connection unit.

### REFERENCE SIGNS LIST

1 Electrical connection unit

2 Metal member

2a Mounting surface

2b Outer peripheral edge

2p Plate portion

2f Fixing portion

3 Fixture

4 Junction box (electrical connection module)

4A First junction box (first electrical connection module)

4B Second junction box (second electrical connection module)

5 Insulating portion

6 Attachment body

7 Cooling mechanism

8 Heat conduction member

10 Housing

11 Bottom wall

11a Outer peripheral edge

12 Peripheral wall

13 Upper wall

14 Through-hole

15 First member

16 Second member

20 Electronic component

20A First electronic component

20B Second electronic component

30 Bus bar (first bus bar)

31 First end

32 Second end

33 Extending portion

40 Heat conduction member

40A First heat conduction member

40B Second heat conduction member

50 Housing

51 Bottom wall

51a Outer peripheral edge

52 Peripheral wall

53 Upper wall

54 Through-hole

55 Third member

56 Fourth member

60 Electronic component

60A Third electronic component

60B Fourth electronic component

70 Bus bar (second bus bar)

71 First end

72 Second end

73 Extending portion

80 Heat conduction member

80A Third heat conduction member

80B Fourth heat conduction member

1. An electrical connection unit comprising:
a first member;
a second member that forms an accommodation space with the first member;
a first electronic component that is disposed in the accommodation space;
a second electronic component that is disposed in the accommodation space;
a first bus bar that includes a first end electrically connected to the first electronic component, a second end electrically connected to the second electronic component, and a plate-shaped extending portion extending along the first member;
a metal member that is disposed on a side opposite to the second member with respect to the first member and includes a plate portion extending along the first member; and
a first heat conduction member, in a case where a direction in which the first member and the second member face each other is a first direction, and an extending direction of the extending portion is a second direction, the first heat conduction member being disposed between the extending portion and the metal member in the first direction, having a smaller outer shape than an outer shape of the extending portion in the second direction, and overlapping the extending portion at a position deviated to a side that is closer to the first end than a center of the extending portion in the second direction when viewed from the first direction.

2. The electrical connection unit according to claim 1,
wherein the first electronic component and the second electronic component are disposed along the first member.

3. The electrical connection unit according to claim 1, further comprising:
a second heat conduction member that is disposed between the extending portion and the metal member in the first direction, has a smaller outer shape than the outer shape of the extending portion in the second direction, is separated from the first heat conduction member, and overlaps the extending portion between the center of the extending portion in the second direction and the second end.

4. The electrical connection unit according to claim 1,
wherein the first member includes a through-hole penetrating the first member in the first direction, and
the first heat conduction member is disposed in the through-hole.

5. The electrical connection unit according to claim 1,
wherein the metal member includes a fixing portion that is attached to a cooling mechanism.

6. The electrical connection unit according to claim 1, comprising:
a first electrical connection module; and
a second electrical connection module, at least either an electrical function or an external connection destination being different from an electrical function or an external connection destination of the first electrical connection module,
wherein the first electrical connection module includes the first member, the second member, the first electronic component, the second electronic component, the first bus bar, and the first heat conduction member,
the second electrical connection module includes a third member, a fourth member that forms an accommodation space with the third member, a third electronic component that is disposed between the third member and the fourth member, and a second bus bar that is electrically connected to the third electronic component, and
the metal member overlaps the first electrical connection module and the second electrical connection module when viewed from the first direction.

7. The electrical connection unit according to claim 6,
wherein the second bus bar includes a plate-shaped extending portion extending along the third member, and
the second electrical connection module further includes a third heat conduction member that is disposed between the extending portion of the second bus bar and the metal member in the first direction.

8. An electrical connection unit comprising:
a first member;
a second member that forms an accommodation space with the first member;
a first electronic component that is disposed in the accommodation space;
a second electronic component that is disposed in the accommodation space;
a first bus bar that includes a first end electrically connected to the first electronic component, a second end electrically connected to the second electronic component, and a plate-shaped extending portion extending along the first member;
a metal member that is disposed on a side opposite to the second member with respect to the first member and includes a plate portion extending along the first member; and
a first heat conduction member, in a case where a direction in which the first member and the second member face each other is a first direction, and an extending direction of the extending portion is a second direction, the first heat conduction member being disposed between the extending portion and the metal member in the first direction, having a smaller outer shape than a half of an outer shape of the extending portion in the second direction, and overlapping the extending portion between a center of the extending portion in the second direction and the first end.

9. An electrical connection unit comprising:
a first electrical connection module;
a second electrical connection module, at least either an electrical function or an external connection destination being different from an electrical function or an external connection destination of the first electrical connection module; and
a metal member,
wherein the first electrical connection module includes
a first member,
a second member that forms a first accommodation space with the first member,
a first electronic component that is disposed in the first accommodation space,
a second electronic component that is disposed in the first accommodation space,
a first bus bar that includes a first end electrically connected to the first electronic component, a second end electrically connected to the second electronic component, and a plate-shaped extending portion extending along the first member, and
a first heat conduction member that is disposed between the extending portion and the metal member in a first direction in a case where a direction in which the first member and the second member face each other is the first direction,
wherein the second electrical connection module includes
a third member,
a fourth member that forms a second accommodation space with the third member,
a third electronic component that is disposed in the second accommodation space, and
a second bus bar that is electrically connected to the third electronic component, and
wherein the metal member overlaps the first electrical connection module and the second electrical connection module when viewed from the first direction.
